(19) United States
(12) Patent Application Publication
(10) Pub. No.: US 2008/0237806 A1
(43) Pub. Date: Oct. 2, 2008

(54) THROUGH-ELECTRODE AND SEMICONDUCTOR DEVICE

(75) Inventor: Shiro UCHIYAMA, Tokyo (JP)

Correspondence Address: YOUNG & THOMPSON, 209 Madison Street, Suite 500, ALEXANDRIA, VA, 22314, US

(73) Assignee: ELPIDA MEMORY, INC., TOKYO (JP)

(21) Appl. No.: 12/054,453

(22) Filed: Mar. 25, 2008

(30) Foreign Application Priority Data
Mar. 28, 2007 (JP) 2007-083331

(51) Int. Cl. H01L 29/40

(52) U.S. Cl. 257/621; 257/E29.111

(57) ABSTRACT

A three-dimensional semiconductor device is produced by laminating a plurality of semiconductor chips having through-electrodes running through semiconductor substrates, wherein each through-electrode includes an internal electrode, a ring-shaped semiconductor, and an external electrode. The internal electrode is formed using an internal conductive film and includes a plurality of pillar semiconductors, each of which is formed in a rectangular shape or a polygonal shape. The pillar semiconductors are each arranged with a prescribed distance therebetween in connection with the ring-shaped semiconductor. The internal conductive film is embedded in regions between the ring-shaped semiconductor and the pillar semiconductors and between the pillar semiconductors adjoining together. This makes it possible to form trenches having uniform depth, thus realizing a high-speed film growth with respect to the conductive film.

### BACKGROUND OF THE INVENTION

1. Field of the Invention

The present invention relates to through-electrodes and semiconductor devices, and in particular to three-dimensional semiconductor devices for laminating a plurality of semiconductor chips having through-electrodes.

The present application claims priority on Japanese Patent Application No. 2007-83331, the content of which is incorporated herein by reference.

2. Description of the Related Art

Recently, various types of three-dimensional semiconductor devices for laminating a plurality of semiconductor chips have been developed. A typical example of a three-dimensional semiconductor device is designed such that a plurality of semiconductor chips are laminated together in multiple layers three-dimensionally formed on a semiconductor substrate, wherein a plurality of through-electrodes run through the semiconductor chips so as to establish electric conduction between semiconductor chips and wiring patterns formed on the semiconductor substrate.

Conventionally-known semiconductor devices having through-electrodes have been disclosed in various documents such as Patent Documents 1 to 3.
Patent Document 1: Japanese Unexamined Patent Application Publication No. 2003-17558.
Patent Document 2: Japanese Unexamined Patent Application Publication No. 2002-289623.
Patent Document 3: Japanese Unexamined Patent Application Publication No. 2006-261403.

Conventionally, through-electrodes are formed in such a way that holes having diameters of several tens of micro-meters (μm) are formed in a semiconductor substrate; insulating films whose thickness ranges from several hundreds of nano-meters (nm) to several micro-meters (μm) are formed in holes so as to secure insulation between side walls of holes and the semiconductor substrate; conduction films are embedded in remaining gaps of holes; then, the surface of the semiconductor substrate is subjected to planation processing.

FIG. 6A is an illustration partly in cross section showing the overall structure of a conventionally-known semiconductor device A. The semiconductor device A is formed by sequentially laminating semiconductor chips 3, 4, and 5 on a semiconductor substrate 1. A plurality of through-electrodes 7 are formed to run through respective semiconductor chips 3, 4, and 5 and are connected together via bumps 6, thus establishing conduction with a wiring electrode 2 formed on the semiconductor substrate 1. FIG. 6B is a sectional view of a section B shown in FIG. 6A. It shows that the through-electrode 7 is constituted of an internal conductive film 7a and an internal insulating film 7b.

The internal insulating film 7b is formed to secure insulation and to produce a capacitance. Semiconductor devices having through-electrodes of high capacitances suffer from problems in that high-frequency data transfer cannot be performed due to disturbances of waveforms. In order to reduce capacitances, it is necessary to use specific materials having low dielectric constants or to increase the thickness of insulating films of through-electrodes.

Presently, appropriate materials cannot be found as insulating materials of through-electrodes having different dielectric constants. When the thickness of insulating films embedded in through-electrodes is increased, it takes a long time to embed insulating films in through-electrodes, thus increasing the manufacturing load. In addition, insulating films of through-electrodes suffer from problems due to irregular qualities thereof and due to dispersions of electric characteristics.

Patent Document 1 teaches that holes having diameters of several tens of micro-meters (μm) are formed in a semiconductor substrate; holes are filled with coated insulating films; then, holes are etched again; conductive films are formed in the holes, thus forming through-electrodes having no cavity in conductive films. However, through-electrodes have low capacitance with the semiconductor substrate and are not applied with conductive films having regular quality.

Patent Document 2 teaches that a second insulating region is formed outside of a through-electrode so as to avoid the occurrence of short-circuiting between the through-electrode and the semiconductor substrate. However, similar to Patent Document 1, this through-electrode has a low capacitance with the semiconductor substrate and is not applied with a conductive film having regular quality.

Patent Document 3 teaches another example of the through-electrode, which is produced in consideration of the aforementioned circumstances. FIG. 7 is a cross-sectional view showing the structure of a through-electrode D. FIG. 8A is a horizontal sectional view taken along line C-C in FIG. 7; and FIG. 8B is an enlarged view showing the relationship between pillar semiconductors 11d formed at positions d1 to d4 in FIG. 8A. In the through-electrode D, four pillar semiconductors 11d are arranged in the upper-left corner shown in FIG. 8A, wherein sectional centers thereof are designated by the positions d1 to d4.

The through-electrode D is formed to run through a semiconductor substrate 11 and is constituted of an internal electrode 12, a ring-shaped semiconductor 11a, and an external electrode 14. The internal electrode 12 is constituted of sixteen pillar semiconductors 11d having square sectional shapes, internal insulating films 3 covering the side surfaces of the pillar semiconductors 11d and internal conductive films 12a. The pillar semiconductors 11d are formed in the conductive films 12a in an isotropic lattice manner.

The through-electrode D is formed in such a way that trenches are formed in prescribed regions except for the pillar semiconductors 11d and the ring-shaped semiconductor 11a; then, insulating films and conductive films are formed in trenches. Silicon etching is performed to form trenches, the depths of which depend upon the shapes and arrangements of the pillar semiconductors 11d. An etchant may be difficult to flow in trenches formed in a region in which the pillar semiconductors 11d are concentrated in a high density; hence, it is very difficult to form trenches having large depths. In order to make the depths of trenches formed between the pillar semiconductors 11d uniform, it is necessary to form the pillar semiconductors 11d with equal spacing therebetween.

As shown in FIG. 8B, the depth of a trench depends upon the distance between the two adjacent pillar semiconductors 11d positioned in parallel with each other, wherein the distance is measured based on the center of a shortest line connecting between the adjacent pillar semiconductors 11d; hence, it depends upon a distance q lying between a center n of a line segment connecting between the positions d1 and d2 and the position d3. The distance q is equal to the distance between the center n and the position d1 as well. In addition, the depth of a trench also depends upon a distance between the two diagonally-adjoining pillar semiconductors 11d, i.e., a distance p between each pillar semiconductor 11d and the center m of a line segment connecting between the positions d1 to d4. In FIG. 8B, the distance p used for defining the depth of a trench in relation to the diagonally-adjoining pillar semiconductors 11d is longer than the distance q used for defining the depth of a trench in relation to the adjacent pillar semiconductors 11d.

In order to form a conductive film (or a bump) 31 in the through-electrode D, trenches are formed at prescribed regions except for the pillar semiconductors 11d in such a way that a relatively large amount of etchant is introduced into a relatively large space with respect to the diagonal line defined by the distance p between the diagonally-adjoining pillar semiconductors 11d. This causes problems due to micro-loading effects, in which the depths of trenches become large at the center m between the four pillar semiconductors 11d rather than the center n between the adjacent pillar semiconductors 11d, or reverse-micro-loading effects.

In a step for embedding the conductive films 13, it takes a long time to embed the conductive film 13 at the center m between the diagonally-adjoining pillar semiconductors 11d because the space of the center m is larger than the space of the center n; hence, this step is a rate-determining step in manufacturing. That is, the thickness of the conductive film 13 embedded at the center m between the diagonally-adjoining pillar semiconductors 11d becomes larger than the thickness of the conductive film 13 embedded at the center n between the adjacent pillar semiconductors 11d; hence, it is very difficult to secure uniformity with respect to electric characteristics of through-electrodes.

### SUMMARY OF THE INVENTION

It is an object of the present invention to provide a through-electrode of a semiconductor device, in which trenches are each formed with uniform depth, and a conductive film is formed in trenches with uniform thickness at a very high growth speed.

It is another object of the present invention to provide a semiconductor device having the aforementioned through-electrode.

In a first aspect of the present invention, a through-electrode, which runs through a semiconductor substrate and which is insulated from the semiconductor substrate, includes an internal electrode, a ring-shaped semiconductor that is formed to surround the internal electrode, and an external electrode that is formed to surround the ring-shaped semiconductor. The internal electrode is formed using an internal conductive film and includes a plurality of pillar semiconductors, each of which has a rectangular shape or a polygonal shape in cross section and which are formed to adjoin together with a prescribed distance therebetween in connection with the ring-shaped semiconductor, and wherein the internal electrode is embedded in regions between the ring-shaped semiconductor and the pillar semiconductors and between the pillar semiconductors adjoining together.

In the above, the polygonal shape adapted to the pillar semiconductor is formed by adding at least one triangular shape to the rectangular shape. The pillar semiconductors are shifted in position by a half pitch in different lines. The ring-shaped semiconductor and the external electrode are placed in a floating state without being supplied with an electric potential. The internal electrode, the ring-shaped semiconductor, and the external electrode are insulated from each other by way of insulating films.

In addition, the internal electrode includes an internal insulating film in addition to the internal conductive film, so that the pillar semiconductors are each insulated from the internal conductive film via the internal insulating film. Or, the ring-shaped semiconductor is insulated from the internal conductive film via the internal insulating film. Furthermore, the external electrode includes an external conductive film and an external insulating film, so that the ring-shaped semiconductor is insulated from the external conductive film via the external insulating film. The external electrode can also be insulated from the ring-shaped semiconductor and the semiconductor substrate via the external insulating film.

In the above, the external conductive film and the external insulating film are both reduced in thickness in comparison with the internal conductive film and the internal insulating film.

It is possible to further form a plurality of peripheral layers, each of which includes a ring-shaped semiconductor and an external electrode, externally of the existing external electrode.

In this connection, the internal electrode is directly connected to a bump, or the internal electrode is connected to the bump via a connection wire.

In a second aspect of the present invention, a semiconductor device includes a semiconductor substrate, and a through-electrode running through the semiconductor substrate, wherein the through-electrode includes a plurality of pillar semiconductors, a ring-shaped semiconductor, which is formed to surround the pillar semiconductors, a conductive film, which is embedded in regions between the ring-shaped semiconductor and the pillar semiconductors and between the pillar semiconductors adjoining together, and an external electrode arranged externally of the ring-shaped semiconductor. The pillar semiconductors are each formed in a rectangular shape or a polygonal shape in cross section and are arranged to adjoin together with a prescribed distance therebetween.

In the above, an insulating film is formed in a region between the ring-shaped semiconductor and the conductive film. The ring-shaped semiconductor and the external electrode are placed in a floating state without being supplied with an electric potential. The insulating film is embedded in regions between the pillar semiconductors and the conductive film.

In addition, it is possible to further form a plurality of peripheral layers, each of which includes a ring-shaped semiconductor and an external electrode, externally of the existing external electrode.

In this connection, the through-electrode is directly connected to a bump, or it is connected to the bump via a wire, wherein a plurality of semiconductor substrates are laminated together with an electric conduction therebetween via the bump.

As described above, it is possible to form a plurality of trenches having the uniform depth between the ring-shaped semiconductor and the pillar semiconductors, whereby the conductive film having the uniform thickness can be formed by way of high-speed film growth, thus producing the through-electrode with a high efficiency.

### BRIEF DESCRIPTION OF THE DRAWINGS

These and other objects, aspects, and embodiments of the present invention will be described in more detail with reference to the following drawings, in which:

FIG. 1A is an illustration partly in cross section showing a semiconductor device for laminating three semiconductor chips having through-electrodes on a semiconductor substrate in accordance with a preferred embodiment of the present invention;

FIG. 1B is an enlarged view of a section F shown in FIG. 1A in connection with two semiconductor chips having through-electrodes;

FIG. 2A is a horizontal sectional view taken along line H-H in FIG. 1B;

FIG. 2B is an enlarged view showing four pillar electrodes arranged in the upper-left corner of a through-electrode shown in FIG. 2A;

FIG. 3A is a horizontal sectional view of another through-electrode running through a semiconductor chip included in a semiconductor device;

FIG. 3B is an enlarged view showing four pillar semiconductors arranged in the upper-left corner of the through-electrode shown in FIG. 3A;

FIG. 4A is a horizontal sectional view of another through-electrode running through a semiconductor chip included in a semiconductor device;

FIG. 4B is an enlarged view showing four pillar semiconductors arranged in the upper-left corner of the through-electrode shown in FIG. 4A;

FIG. 5A is a cross-sectional view for explaining a first step of a manufacturing method of the through-electrode running through the semiconductor chip shown in FIGS. 1A and 1B;

FIG. 5B is a cross-sectional view for explaining a second step of the manufacturing method of the through-electrode running through the semiconductor chip shown in FIGS. 1A and 1B;

FIG. 5C is a cross-sectional view for explaining a third step of the manufacturing method of the through-electrode running through the semiconductor chip shown in FIGS. 1A and 1B;

FIG. 5D is a cross-sectional view for explaining a fourth step of the manufacturing method of the through-electrode running through the semiconductor chip shown in FIGS. 1A and 1B;

FIG. 5E is a cross-sectional view for explaining a fifth step of the manufacturing method of the through-electrode running through the semiconductor chip shown in FIGS. 1A and 1B;

FIG. 6A is an illustration partly in cross section showing the structure of a conventionally-known three-dimensional semiconductor device having through-electrodes;

FIG. 6B is an enlarged view of a section B shown in FIG. 6A;

FIG. 7 is a cross-sectional view of the through-electrode;

FIG. 8A is a horizontal sectional view taken along line C-C in FIG. 7; and

FIG. 8B is an enlarged view showing the relationship between four pillar semiconductors included in the through-electrode shown in FIG. 8A.

### DESCRIPTION OF THE PREFERRED EMBODIMENT

The present invention will be described in further detail by way of examples with reference to the accompanying drawings.

### 1. Structure of Semiconductor Device

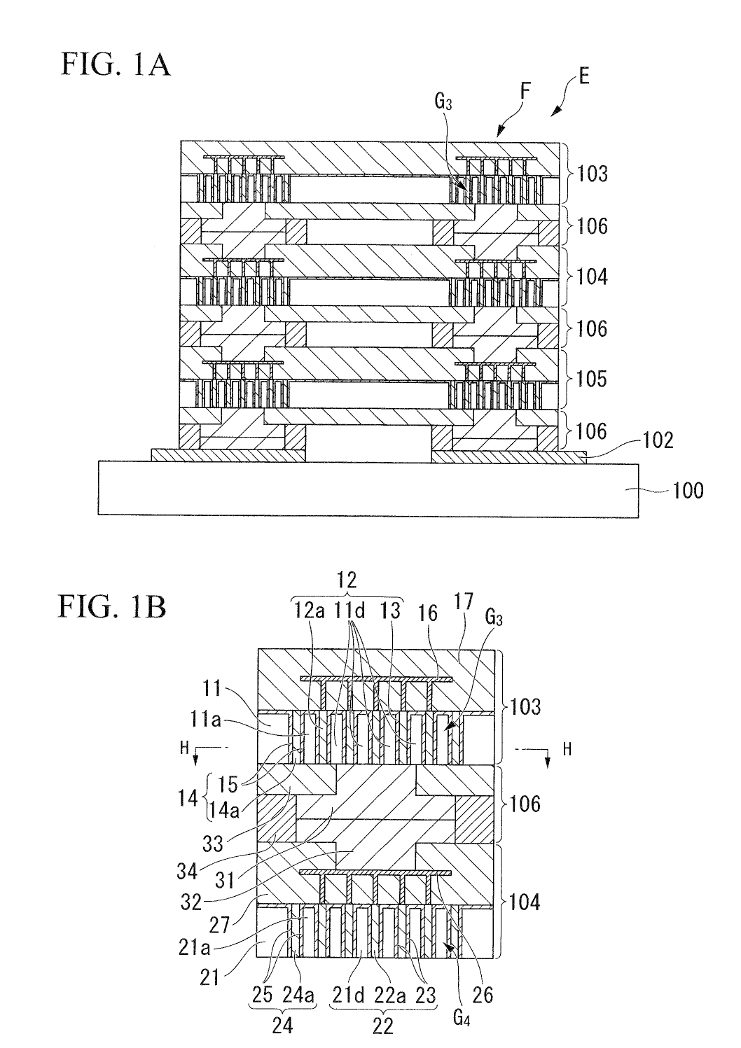

FIG. 1A is an illustration partly in cross section showing a semiconductor device E in accordance with a preferred embodiment of the present invention.

The semiconductor device E is designed such that three semiconductor chips 103, 104, and 105 are mounted on a semiconductor substrate 100. The semiconductor chips 103, 104, and 105 are interconnected together via interconnection portions 106 by way of through-electrodes G3 etc. and are also connected to a wiring pattern 102 formed on the semiconductor substrate 100.

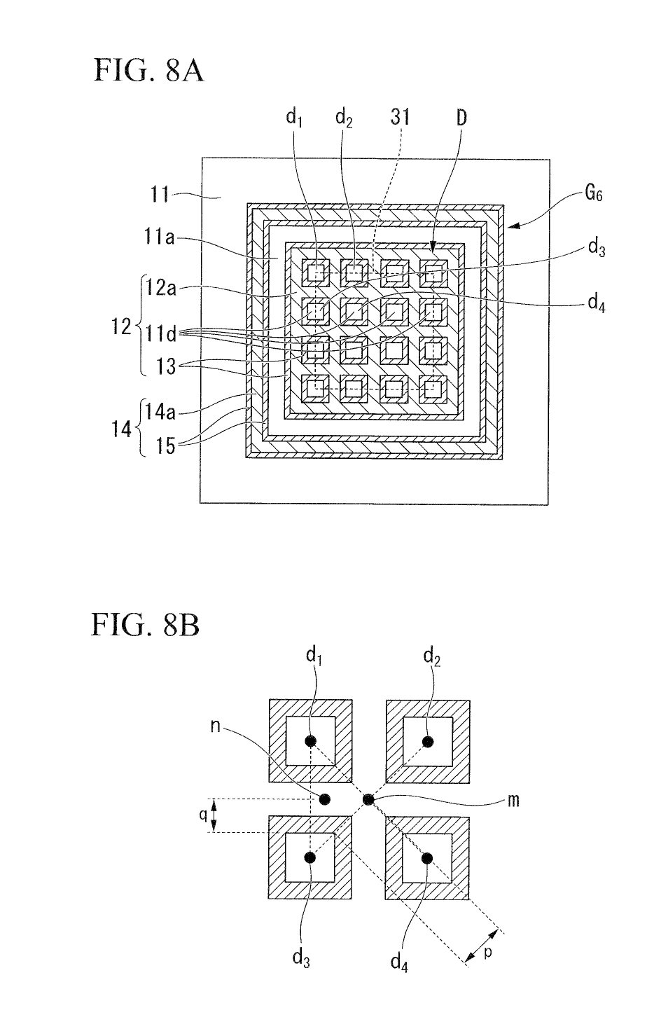

FIG. 1B is an enlarged view of a section F shown in FIG. 1A with regard to the through-electrodes G3 and G4 running through the semiconductor chips 103 and 104, which are interconnected together via the interconnection portion 106, wherein parts identical to those shown in FIG. 8A are designated by the same reference numerals.

The semiconductor chip 103 is formed by laminating a semiconductor substrate 11 and an insulating film 17 together. The through-electrode G3 is formed in the semiconductor substrate 11 and is connected to a connection wire 16 formed inside of the insulating film 17. The through-electrode G3 is constituted of an internal electrode 12, a ring-shaped semiconductor 11a surrounding the internal electrode 12, and an external electrode 14 surrounding the internal electrode 12 and the ring-shaped semiconductor 11.

The internal electrode 12 is constituted of an internal conductive film 12a, an internal insulating film 13, and pillar semiconductors 11d. The pillar semiconductors 11d are disposed on the interconnection portion 106, and the exterior surfaces thereof are covered with the internal insulating film 13. The internal conductive film 12a is embedded in the spacing between the pillar semiconductors 11d. The pillar semiconductors 11d are connected to a bump 31, which is formed in contact with the backside of the a semiconductor substrate 11. The bump 31 is formed in an opening of an insulating film 33 attached to the backside of the semiconductor substrate 11.

The external electrode 14 is constituted of an external conductive film 14a and an external insulating film 15.

The structure of the semiconductor chip 104 is similar to that of the semiconductor chip 103. That is, the semiconductor chip 104 is formed by laminating a semiconductor substrate 21 and an insulating film 27 together. The through-electrode G4 is formed in the semiconductor substrate 21 and is connected to a connection wire 26 formed inside of the insulating film 27. The through-electrode G4 is constituted of an internal electrode 22, a ring-shaped semiconductor 21a, and an external electrode 24. The internal electrode 22 is constituted of an internal conductive film 22a, an internal insulating film 23, and pillar semiconductors 21d. The pillar semiconductors 21d are disposed on the interconnection portion 106, and the exterior surfaces thereof are covered with the internal insulating film 23. The internal conductive film 22a is embedded in the spacing between the pillar semiconductors 21d. The pillar semiconductors 21d are connected to a bump 32, which is formed in the opening of the insulating film 27. The external electrode 24 is constituted of an external conductive film 24a and an external insulating film 25.

The connection wire 26 is connected to the bump 32, which is connected to the bump 31, thus establishing conduction between the through-electrode G4 of the semiconductor chip 104 and the through-electrode G3 of the semiconductor chip 103.

The side portions of the bumps 31 and 32 are filled with an adhesive 34 composed of a resin material, thus stably holding the semiconductor chips 103 and 104 together. FIGS. 1A and 1B show that the adhesive 34 is formed in only the side portions of the bumps 31 and 32; but it can be formed to fill all the gaps existing between the semiconductor chips 103 and 104.

In the above, all of the external electrode 14 and the ring-shaped semiconductor 11a of the semiconductor chip 103 and the external electrode 24 and the ring-shaped semiconductor 21a of the semiconductor chip 103 are placed in a floating state so that they are not connected to any elements or any wires.

In this connection, it is possible to additionally form semiconductor elements such as transistors and wiring layers on the surfaces of the semiconductor chips 103 and 104 and to connect them to the connection wire 16 and/or the connection wire 26.

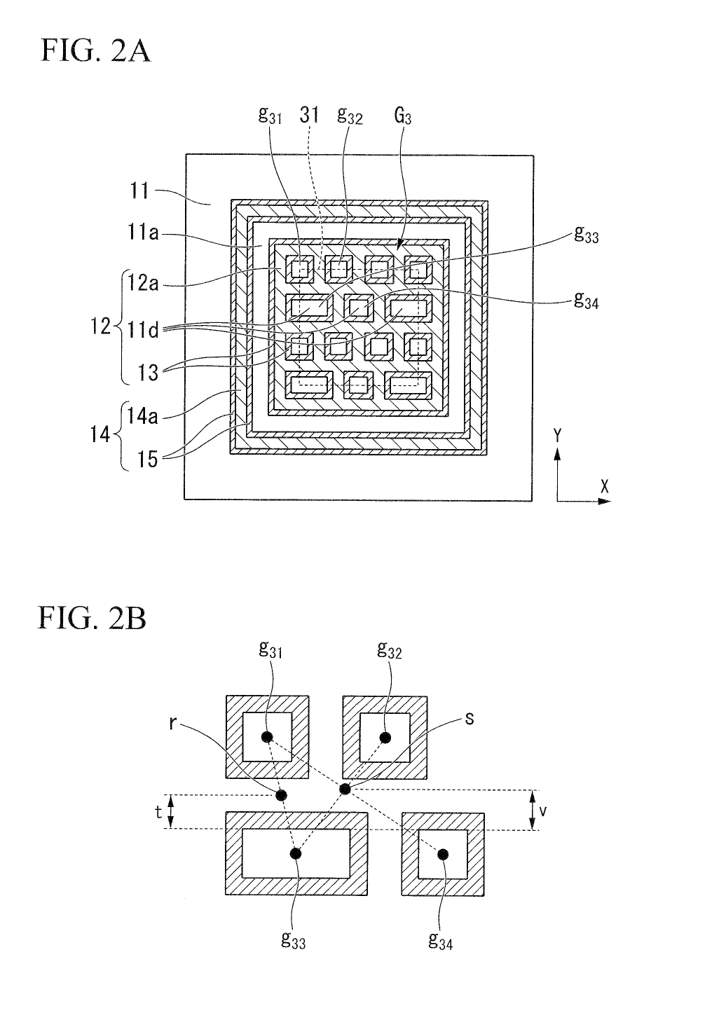

The through-electrode G3 of the semiconductor chip 103 will be described with reference to FIGS. 2A and 2B. FIG. 2A is a horizontal sectional view taken along line H-H in FIG. 1B, and FIG. 2B is an enlarged view showing four pillar semiconductors 11d laid at positions g31 to g34 shown in FIG. 2A.

The through-electrode G3 is constituted of the internal electrode 11, the ring-shaped semiconductor 11a, and the external electrode 14, which are formed on the semiconductor substrate 11.

As shown in FIG. 1B, the internal electrode 12 is constituted of the internal conductive film 12a, the internal insulating film 13, and the pillar semiconductors 11d. A region encompassed by a dotted line in FIG. 2A matches the opening of the insulating film 33 formed in the backside of the semiconductor substrate 11 so as to indicate the position and area of the bump 31.

The external electrode 14 is constituted of the external conductive film 14a and the external insulating film 15 surrounding the external conductive film 14a.

The ring-shaped semiconductor 11a is formed between the internal electrode 12 and the external electrode 14.

It is preferable that the width of the external electrode 14 be identical to or smaller than the distance between the adjacent pillar semiconductors 11d. When the width of the external electrode 14 is set to be smaller than the distance between the adjacent pillar semiconductors 11d, the thickness of the external conductive film 14a, which is formed simultaneously with the formation of conductive films for the through-electrode G3, can be reduced to be smaller than the thickness of the internal conductive film 12a formed between the pillar semiconductors 11d.

It is possible not to form the external conductive film 14a when the external electrode 14 has a very small width. This is because the external electrode 14 is in a floating state and does not actually function as an electrode so that the external electrode 14 can be formed using only the external insulating film 15.

The ring-shaped semiconductor 11a and the external electrode 14 are formed between the semiconductor substrate 11 and the internal electrode 12. Since the ring-shaped semiconductor 11a and the external electrode 14 are both placed in a floating state, it is possible to remarkably reduce the capacitance between the internal electrode 12 and the semiconductor substrate 11. Reducing the capacitance enables high-speed data transfer; hence, it is possible to form through-electrodes having superior electric characteristics.

The internal insulating film 13, the ring-shaped semiconductor 11a, the external insulating film 15, and the external electrode 14 collectively serve as a guard ring between the semiconductor substrate 11 and the internal electrode 12. This remarkably reduces the capacitance between the semiconductor substrate 11 and the internal electrode 12. Due to the reduced capacitance between the semiconductor substrate 11 and the internal electrode 12, it is possible to reduce insulation resistance; hence, it is possible to reduce the thickness of the internal insulating film 13 and the thickness of the external insulating film 15 in comparison with the thickness of insulating films formed in conventionally-known through-electrodes.

The fourteen pillar semiconductors 11d are formed in the through-electrode G3 shown in FIG. 2A, wherein the ten pillar semiconductors 11d each have square shapes in their cross sections, while the remaining four pillar semiconductors 11d each have rectangular shapes in cross section.

In FIG. 2A, the centers of the cross sections of the four pillar semiconductors 11d arranged in the upper-left corner of the through-electrode G3 are designated by positions g31 to g34, which are shown in FIG. 2B. Both the two pillar semiconductors 11d at the positions g31 and g32 have square shapes in their cross sections. That is, the four pillar semiconductors 11d having square shapes in their cross sections are each aligned in line in an X-axis direction with the same distance therebetween.

The pillar semiconductor 11d having a rectangular shape in cross section is formed at the position g33 adjoining the position g31 in a Y-axis direction. That is, the four pillar semiconductors 11d having different shapes in their cross sections are aligned in the Y-axis direction with the same distance therebetween.

In addition, the pillar semiconductor 11d having a square shape in its cross section is formed at the position g34 adjoining the position g33, at which the pillar semiconductor 11d having a rectangular shape in its cross section is formed, in the X-axis direction. In addition, the pillar semiconductor 11d having a rectangular shape in its cross section is formed to adjoin the pillar semiconductor 11d having the square shape in its cross section in the X-axis direction. Thus, the three pillar semiconductors 11d are aligned in the X-axis direction with the same distance therebetween.

The pillar semiconductors 11d having square shapes in their cross sections belonging to different lines lying in the Y-axis direction are aligned in such a way that the center thereof is shifted by a half pitch in the X-axis direction, wherein one pitch corresponds to the distance between the pillar semiconductors. In FIG. 2B, the center of the pillar semiconductor 11d at the position g34 is shifted by a half pitch in the X-axis direction in comparison with the pillar semiconductor 11d at the position g32. The distance between the rectangular-shaped pillar semiconductor 11d of the position g33 and the square-shaped pillar semiconductor 11d of the position g34 substantially matches the distance between the adjacent square-shaped pillar semiconductors 11d.

As described above, all the pillar semiconductors 11d are aligned with substantially the same distance therebetween, wherein the insulating films formed on the side surfaces of the pillar semiconductors 11d are formed in an isotropic manner, thus making remaining spaces have substantially the same width. When conductive films are embedded in spaces, it is possible to form the internal conductive film 12a uniformly having the same thickness.

The thickness of the internal conductive film 12a depends upon the distance between the pillar semiconductors 11d and the thickness of the internal insulating film 13. Since both the distance between the pillar semiconductors 11d and the thickness of the internal insulating film 13 can be controlled with high precision, it is possible to control the thickness of the internal conductive film 12 at a high precision. That is, it is possible to form a “thin” internal conductive film 12 whose thickness is controlled uniformly.

As shown in FIG. 2B, the depth of trenches formed between the adjacent pillar semiconductors 11d depends upon a distance t ranging from a center r of a line segment connecting between the positions g31 and g33 to the pillar semiconductor 11d of the position g33. The distance t corresponds to the distance from the center r to the pillar semiconductor 11d of the position g31 as well. The depth of trenches formed between the four pillar semiconductors 11d substantially aligned on a diagonal line depends upon the shortest one of respective distances ranging from the center s of a line segment connecting between the positions g31 to g34 to the pillar semiconductors 11d. Specifically, it depends upon the distance v between the center s and the position g33. The distance v is substantially identical to the distance r.

Trenches to be filled with the conductive film 31 for use in the through-electrode G3 are formed by way of silicon etching, wherein an etchant can be uniformly introduced into spaces between the pillar semiconductors 11d. Thus, it is possible to solve the foregoing problems due to micro-loading effects or reverse-micro-loading effects, which may occur dependent upon different depths of trenches formed in conventionally-known through-electrodes.

In an embedding step of the conductive film 31, the spaces for embedding the conductive film 31 do not deviate in size at different positions; hence, it is possible to remarkably reduce the film growth time for the embedding of the conductive film 31, that is, it is possible to realize high-speed film growth in manufacturing.

Since the uniform thickness of the conductive film 31 can be realized at any position, it is possible to secure uniform electric characteristics in the through-electrode G3.

It is possible to modify the patterns of through-electrodes in a variety of ways.

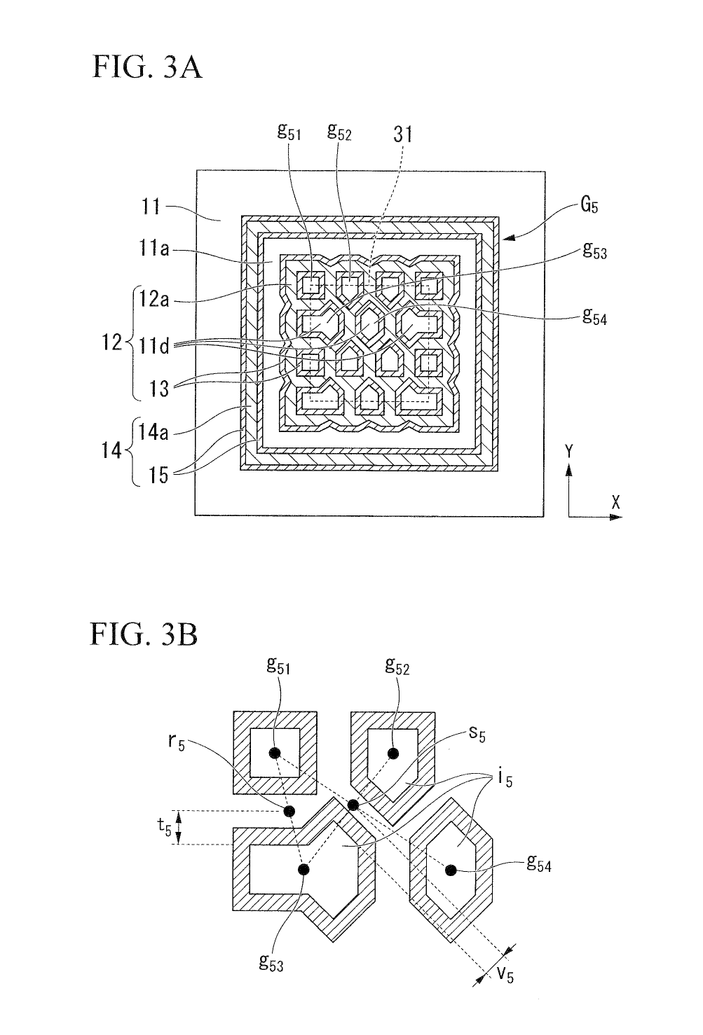

Next, a through-electrode G5 will be described with reference to FIGS. 3A and 3B. FIG. 3A is a horizontal sectional view of the through-electrode G5, and FIG. 3B is an enlarged view showing four pillar semiconductors 11d located at positions g51 to g54 in the upper-left corner of the through-electrode G5 shown in FIG. 3A.

Similar to the through-electrode G3 shown in FIG. 2A, the through-electrode G5 is constituted of the internal electrode 12, the ring-shaped semiconductor 11a, and the external electrode 14 in FIG. 3A, wherein parts identical to those shown in FIG. 2A are designated by the same reference numerals; hence, the duplicate description thereof will be omitted.

Comparing the horizontal section views of FIGS. 2A and 3A, three differences are found therebetween.

A first difference is that triangular projections i5 are formed in the ring-shaped semiconductor 11a and the internal insulating film 13 in correspondence with gaps h between the pillar semiconductors 11d.

A second difference is that, within the ten square-shaped pillar semiconductors 11d shown in FIG. 2A, five pillar semiconductors 11d are each formed in a pentagonal shape (in which the triangular projections i5 are added to the upper portion or the lower portion of the square shape), and one pillar semiconductor 11d is formed in a hexagonal shape (in which the triangular projections i5 are added to the upper portion and lower portion of the square shape). One side length of the triangular projection i5 substantially matches one side length of the square shape of the pillar semiconductor 11d. The triangular projections i5 are formed in correspondence with the gaps h between the pillar semiconductors 11d; hence, they are not formed in proximity to the external electrode 14 arranged externally of the gaps h.

A third difference is that, within the four rectangular-shaped pillar semiconductors 11d, two pillar semiconductors 11d are each formed in a hexagonal shape (in which the triangular projection i5 is added to the rectangular shape), and two pillar semiconductors 11d are each formed in an octagonal shape (in which the triangular projections i5 are added to the rectangular shape). Similar to the pentagonal pillar semiconductors 11d and the hexagonal pillar semiconductor 11d, which are each formed by adding the triangular projection(s) i5 to the square shape, the triangular projections i5 added to the rectangular-shaped pillar semiconductors 11d, which are thus formed in the hexagonal shape and octagonal shape, are formed in correspondence with the gaps h between the pillar semiconductors 11d; hence, they are not formed in proximity to the external electrode 14 arranged externally of the gaps h.

As shown in FIG. 3B, the depth of trenches formed between the adjacent pillar semiconductors 11d depends upon a distance t5 ranging from the center r5 of a line segment connecting between the positions g51 and g53 to the pillar semiconductor 11d of the position g53. The distance t5 matches the distance from the center r5 to the pillar semiconductor 11d of the position g51 as well. The depth of trenches formed between the four pillar semiconductors 11d aligned on diagonal lines depends upon the shortest distance among the distances of the four pillar semiconductors 11d measured from a center s5 between the positions g51 to g54. That is, it depends upon a distance v5 ranging from the center s5 to the pillar semiconductor 11d of the position g53. The distance v5 is substantially identical to the distance r5.

Silicon etching is performed to form trenches, which are filled with the conductive film 31 for use in the through-electrode G5, an etchant can be uniformly introduced into gaps between the pillar semiconductors 11d; hence, it is possible to solve problems due to micro-loading effects (in which depths of trenches differ in positions) and reverse-micro-loading effects.

In an embedding step of the conductive film 31, the spaces for embedding the conductive film 31 do not deviate in size at different positions; hence, it is possible to remarkably reduce the film growth time for the embedding of the conductive film 31, that is, it is possible to realize a high-speed film growth in manufacturing.

Since the uniform thickness of the conductive film 31 can be realized at any position, it is possible to secure uniform electric characteristics in the through-electrode G5.

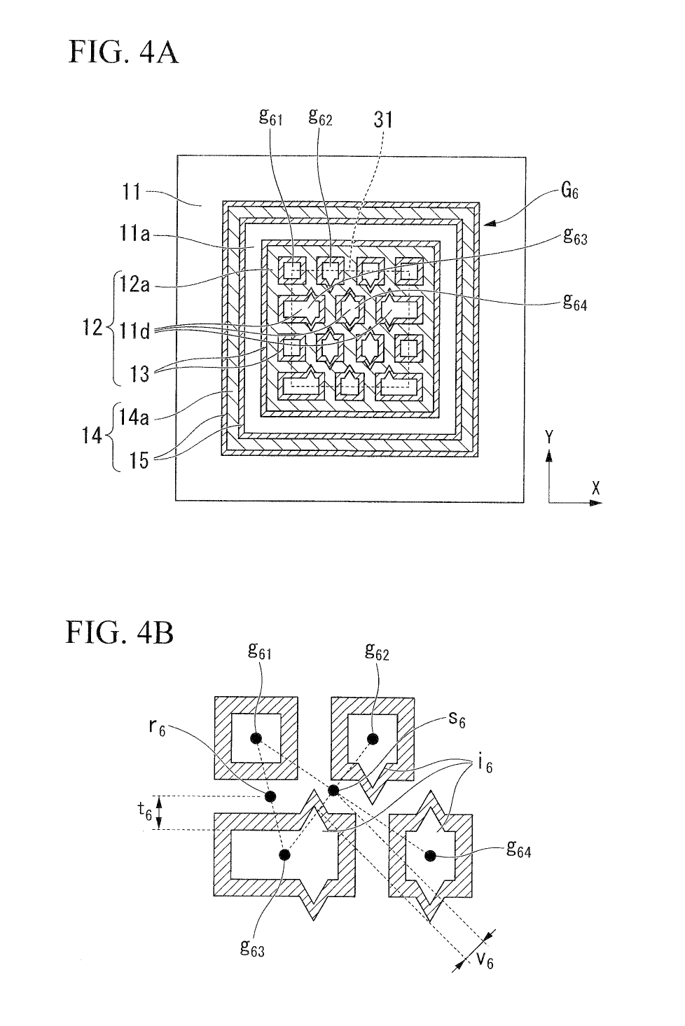

Next, a through-electrode G6 will be described with reference to FIGS. 4A and 4B. FIG. 4A is a horizontal sectional view of the through-electrode G6, and FIG. 4B is an enlarged view showing four pillar semiconductors 11d located at positions g61 to g64 arranged in the upper-left corner of the through-electrode G6 shown in FIG. 4A.

Similar to the foregoing through-electrodes G3 and G5, the through-electrode G6 is constituted of the internal electrode 12, the ring-shaped semiconductor 11a, and the external electrode 14, wherein parts identical to those shown in FIGS. 2A, 2B, 3A, and 3B are designated by the same reference numerals; hence, the duplicate descriptions thereof will be omitted.

Comparing the horizontal sectional views of FIGS. 3A and 4A, one difference is found therebetween.

In FIGS. 4A and 4B, triangular projections i6 are added to the pillar semiconductors 11d having square shapes and rectangular shapes in their cross sections and are reduced in size compared with the triangular projections i5 shown in FIGS. 3A and 3B.

That is, within the ten square-shaped pillar semiconductors 11d shown in FIG. 2A, three pillar semiconductors 11d are each added with one triangular projection i6 and thus formed in a heptagonal shape in its cross section, and other three pillar semiconductors 11d are each added with two triangular projections i6 and thus formed in a ten-sided polygonal shape in its cross section. One side length of the triangular projection i6 is shorter than one side length of the square shape of the pillar semiconductor 11d.

Within the four rectangular-shaped pillar semiconductors 11d shown in FIG. 2A, two pillar semiconductors 11d are each added with one triangular projection i6 and thus formed in a heptagonal shape in its cross section, and other two pillar semiconductors 11d are each added with two triangular projections i6 and thus formed in a ten-sided polygonal shape in its cross section.

As shown in FIG. 4B, the depth of trenches formed between the adjacent pillar semiconductors 11d depends upon a distance t6 ranging from a center r6 of a line segment connecting between the positions g61 and g63 and the pillar semiconductor 11d of the position g63. The distance t6 substantially matches the distance between the center t6 and the pillar semiconductor 11d of the position g61 as well. The depth of trenches formed between four pillar semiconductors 11d aligned on diagonal lines depends upon the shortest distance among the distances ranging from the center s6 to the pillar semiconductors 11d of the positions g61 o g64. That is, it depends upon the distance v6 ranging from the center s6 to the pillar semiconductor 11d of the position g63. The distance v6 is substantially identical to the distance t6.

Silicon etching is performed to form trenches, which are filled with the conductive film 31 for use in the through-electrode G6, wherein an etchant can be uniformly introduced into spaces between the pillar semiconductors 11d; hence, it is possible to solve problems due to micro-loading effects (in which depths of trenches differ in positions) and reverse-micro-loading effects.

In an embedding step of the conductive film 31, the spaces for embedding the conductive film 31 do not deviate in size at different positions; hence, it is possible to remarkably reduce the film growth time for the embedding of the conductive film 31, that is, it is possible to realize a high-speed film growth in manufacturing.

Since the uniform thickness of the conductive film 31 can be realized at any positions, it is possible to secure uniform electric characteristics in the through-electrode G6.

As described above, the pillar semiconductors 11d are formed in various polygonal sectional shapes by adding triangular projections i5 and i6 to square shapes and rectangular shapes. The triangular projections i5 and i6 are not necessarily shaped in prescribed dimensions; that is, one side length thereof can be set to be substantially identical to one side length of a square shape or to be smaller than one side length of a square shape. Any type of triangular shape can be applied to the triangular projections i5 and i6; however, it is preferable to apply symmetrical triangular shapes such as an equilateral triangle or an isosceles triangle. In addition, a single triangular projection i5 or i6 is not necessarily formed on one side of a square shape or a rectangular shape; hence, it is possible to form plural triangular projections i5 or i6 on one side of a square shape or a rectangular shape.

### 2. Manufacturing Method of Semiconductor Device

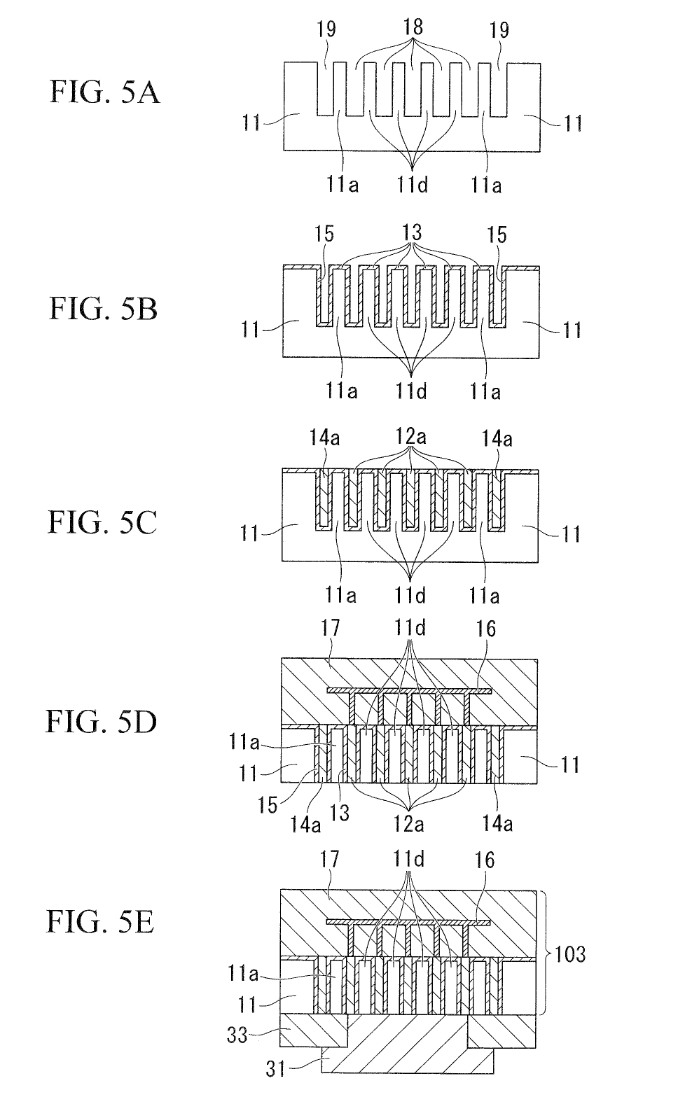

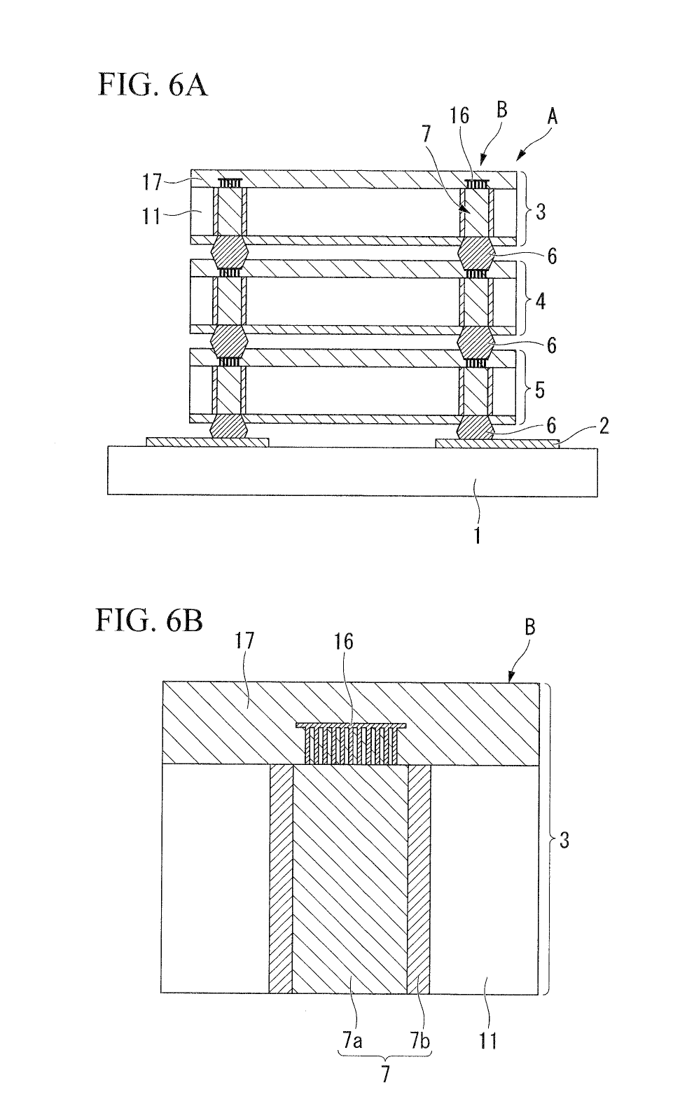

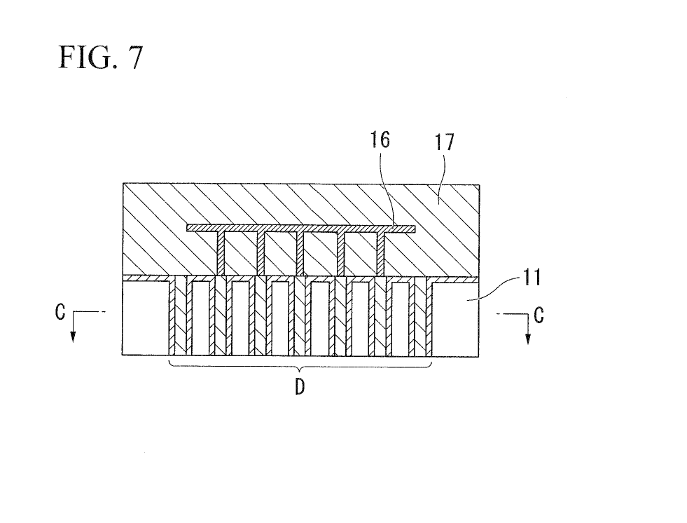

Next, a manufacturing method of the three-dimensional semiconductor device E shown in FIG. 1A will be described with reference to FIGS. 5A to 5E, wherein parts identical to those shown in FIG. 1B are designated by the same reference numerals. Specifically, it is described with respect to the through-electrode G3 formed in the section F of the semiconductor chip 103.

In a first step of the manufacturing method shown in FIG. 5A, trenches 18 and 19 are formed at prescribed positions of the semiconductor substrate 11 by way of lithography and etching, wherein all the trenches 18 and 19 are each formed with the same width and the same depth.

Pillar portions are formed due to the formation of the trenches 18 and 19 and are then accompanied with conductive films and insulating films so as to form the pillar semiconductors 11d. In addition, a ring-shaped portion is also formed due to the formation of the trenches 18 and 19 and are then accompanied with a conductive film and an insulating film so as to form the ring-shaped semiconductor 11a.

It is preferable to form the trenches 18 with the same width, so that it is possible to uniform the thickness of insulating films.

It is preferable to form the trenches 19 with the same width, which is substantially identical to or smaller than the width of the trenches 18. The external electrode 14 is formed using the trenches 19, wherein it is not applied with electric potential and is placed in a floating state. By reducing the width of the trenches 19, it is possible to completely embed insulating films in the trenches 19, which thus no longer need conductive films.

In a second step of the manufacturing method shown in FIG. 5B, an insulating film is formed to entirely cover the overall surface of the semiconductor substrate 11 in an isotropic manner. The prescribed portion of the insulating film, which is formed in the trenches 18, will be referred to as the internal insulating film 13, and the other portion of the insulating film, which is formed in the trenches 19, will be referred to as the external insulating film 15.

The insulating film can be formed by any method. For example, a silicon material of the semiconductor substrate 11 is subjected to thermal oxidation so as to produce SiO₂ for use in the insulating film.

Next, a conductive film is formed to entirely cover the overall surface of the semiconductor substrate 11 by way of chemical vapor deposition (CVD) in an isotropic manner. That is, the conductive film is formed in an isotropic manner on the internal insulating film 13 and the external insulating film 15 formed inside of the trenches 18 and 19, so that it is embedded in remaining gaps of the trenches 18 and 19.

The conductive film is embedded in the trenches 18 having the same width, i.e., a plurality of small gaps that are equally divided by the pillar semiconductors 11d; hence, it is possible to form the thin conductive film having uniform thickness and uniform quality.

In a third step of the manufacturing method shown in FIG. 5C, the conductive film formed on the surface of the semiconductor substrate 11 is removed so as to isolate the internal conductive film 12a, which is then subjected to planation processing.

The prescribed portion of the conductive film formed inside of the trenches 18 will be referred to as the internal conductive film 12a, and the other portion of the conductive film formed inside of the trenches 19 will be referred to as the external conductive film 14a.

The internal electrode 12 is formed using the pillar semiconductors 11d, the internal insulating film 13, and the internal conductive film 12a. The external electrode 14 is formed using the external insulating film 15 and the external conductive film 14a.

As the material for use in the conductive film, it is possible to list polysilicon, tungsten, and copper. The conductive film is not necessarily formed by way of CVD, which can be substituted by a dry process such as sputtering and a wet process such as plating.

In a fourth step of the manufacturing method shown in FIG. 5D, the connection wire 16 and the insulating film 17 are formed on the semiconductor substrate 11. The connection wire 16 is connected to the internal electrode 12, and the insulating film 17 is formed to protect the semiconductor chip 103 from environmental factors.

The backside of the semiconductor substrate 11 polished so as to expose the internal electrode 12 and the external electrode 14, thus realizing the structure shown in FIG. 5D.

In the above, it is possible to perform double polishing in such a way that the backside of the semiconductor substrate 11 is polished to some extent, then, secondary polishing is performed using wet polishes or dry polishes.

In this connection, it is possible to form transistors, capacitors, and resistors simultaneously with the fourth step of the manufacturing method.

In a fifth step of the manufacturing method, the insulating film 33 is formed on the backside of the semiconductor substrate 11 already subjected to polishing; then, a via is formed so as to form an opening in connection with the internal electrode 12; thereafter, the bump 31 is formed in the opening.

Lastly, the product that is produced in accordance with the manufacturing method is divided into individual pieces, thus completely forming the semiconductor chip 103 having the through-hole G3 as shown in FIG. 5E.

In the above, the bump 31 is not necessarily formed on the backside of the semiconductor substrate 11 but can be formed on the surface of the semiconductor substrate 11. Alternatively, it is possible to form bumps 31 on both the surface and backside of the semiconductor substrate 1.

The bump 31 is formed on the surface of the semiconductor substrate 11 in such a way that it is connected to the internal electrode 12 or the connection wire 16.

FIG. 1B is a cross-sectional view of the section F, in which the semiconductor chip 103 is connected to the semiconductor chip 104 via the interconnection portion 106 by way of the through-electrodes G3 and G4. The bump 31 is formed on the backside of the semiconductor chip 103, while the bump 32 is formed on the surface of the semiconductor chip 104, wherein the bumps 31 and 32 are interconnected together so as to establish electric conduction from the connection wire 16 of the semiconductor chip 103 to the internal electrode 22.

In order to secure desired reliabilities and desired electric characteristics with respect to the semiconductor chips 103 and 104, the interconnection portion 106 is fixed by means of the adhesive 34.

It is possible to form transistors, capacitors, and resistors on each semiconductor chip during its manufacturing process or after its manufacturing process. Each semiconductor chip not having transistors can be simply used as a through-electrode serving as an interposer.

Next, effects of the present embodiment will be described below.
1. The through-electrode G3 arranges the pillar semiconductors 11d in such a way that they are shifted in position by a half pitch in the X-axis direction in different lines lying in the Y-axis direction., wherein the pillar semiconductors 11d have square shapes and rectangular shapes in their cross sections. This makes it possible to uniform the prescribed distance for defining the depth of trenches formed between the pillar semiconductors 11d. Thus, it is possible to reduce micro-loading effects and reverse-micro-loading effects and to uniform the depth of trenches.
2. The through-electrodes G5 and G6 arrange the pillar semiconductors 11d in such a way that they are shifted in position by a half pitch in the X-axis direction in different lines lying in the Y-axis direction, wherein the pillar semiconductors 11d basically have square shapes and rectangular shapes, which are added with triangular projections so as to form polygonal shapes in their cross sections. This makes it possible to make the prescribed distance for defining the depth of trenches formed between the pillar semiconductors 11d uniform. Thus, it is possible to reduce micro-loading effects and reverse-micro-loading effects and to make the depth of trenches uniform.
3. Each through-electrode arranges a plurality of pillar semiconductors having the aforementioned cross-sectional shapes and arrangements so as to make the depth of trenches uniform. This makes it possible to control the thickness of conductive films formed in trenches with thinness, uniformity, and high precision. Thus, it is possible to improve electric characteristics of each through-electrode, and it is possible to reduce dispersions of electric characteristics.
4. Each through-electrode arranges a plurality of pillar semiconductors having the aforementioned cross-sectional shapes and arrangements so as to make the depth of trenches uniform. By uniforming the thickness of conductive films embedded in trenches, it is possible to realize a high film growth speed with regard to conductive films formed in trenches, thus improving production efficiency.
5. By changing shapes of internal electrodes and pillar semiconductors, it is possible to change resistances and capacitances included in each through-electrode, which can be thus reduced in impedance.
6. The semiconductor device E includes a plurality of through-electrodes having low impedances, which realizes high-speed transfer between semiconductor chips.

The present invention has industrial applicability to semiconductor manufacturers for producing three-dimensional semiconductor devices for three-dimensionally laminating semiconductor chips including transistors, capacitors, and resistors.

Lastly, the present invention is not necessarily limited to the present embodiment and its associated examples, which can be further modified in a variety of ways within the scope of the invention as defined in the appended claims.

What is claimed is:

1. A through-electrode, which runs through a semiconductor substrate and which is insulated from the semiconductor substrate, comprising:
an internal electrode;
a ring-shaped semiconductor that is formed to surround the internal electrode; and
an external electrode that is formed to surround the ring-shaped semiconductor,
wherein the internal electrode is formed using an internal conductive film and includes a plurality of pillar semiconductors, each of which has a rectangular shape or a polygonal shape in its cross section and which are formed to adjoin together with a prescribed distance therebetween in connection with the ring-shaped semiconductor, and wherein the internal electrode is embedded in regions between the ring-shaped semiconductor and the pillar semiconductors and between the pillar semiconductors adjoining together.

2. A through-electrode according to claim 1, wherein the polygonal shape adapted to the pillar semiconductor is formed by adding at least one triangular shape to the rectangular shape.

3. A through-electrode according to claim 1, wherein the pillar semiconductors are shifted in position by a half pitch in different lines.

4. A through-electrode according to claim 1, wherein the ring-shaped semiconductor and the external electrode are placed in a floating state without being supplied with an electric potential.

5. A through-electrode according to claim 4, wherein the internal electrode, the ring-shaped semiconductor, and the external electrode are insulated from each other by way of insulating films.

6. A through-electrode according to claim 4, wherein the internal electrode includes an internal insulating film in addition to the internal conductive film, so that the pillar semiconductors are each insulated from the internal conductive film via the internal insulating film.

7. A through-electrode according to claim 4, wherein the internal electrode includes an internal insulating film in addition to the internal conductive film, so that the ring-shaped semiconductor is insulated from the internal conductive film via the internal insulating film, and wherein and the external electrode includes an external conductive film and an external insulating film, so that the ring-shaped semiconductor is insulated from the external conductive film via the external insulating film.

8. A through-electrode according to claim 4, wherein the external electrode includes an external conductive film and an external insulating film, so that the external electrode is insulated from the ring-shaped semiconductor and the semiconductor substrate via the external insulating film.

9. A through-electrode according to claim 4, wherein the internal electrode includes an internal insulating film in addition to the internal conductive film, and the external electrode includes an external conductive film and an external insulating film, and wherein the external conductive film and the external insulating film are both reduced in thickness in comparison with the internal conductive film and the internal insulating film.

10. A through-electrode according to claim 4 further comprising a plurality of peripheral layers, each of which includes a ring-shaped semiconductor and an external electrode, externally of the external electrode.

11. A through-electrode according to claim 1, wherein the internal electrode is directly connected to a bump, or the internal electrode is connected to the bump via a connection wire.

12. A semiconductor device comprising:
a semiconductor substrate; and
a through-electrode running through the semiconductor substrate,
wherein the through-electrode includes a plurality of pillar semiconductors, a ring-shaped semiconductor, which is formed to surround the plurality of pillar semiconductors, a conductive film, which is embedded in regions between the ring-shaped semiconductor and the pillar semiconductors and between the pillar semiconductors adjoining together, and an external electrode arranged externally of the ring-shaped semiconductor, and
wherein the pillar semiconductors are each formed in a rectangular shape or a polygonal shape in its cross section and are arranged to adjoin together with a prescribed distance therebetween.

13. A semiconductor device according to claim 12, wherein an insulating film is formed in a region between the ring-shaped semiconductor and the conductive film.

14. A semiconductor device according to claim 13, wherein the ring-shaped semiconductor and the external electrode are placed in a floating state without being supplied with an electric potential.

15. A semiconductor device according to claim 13, wherein the insulating film is embedded in regions between the pillar semiconductors and the conductive film.

16. A semiconductor device according to claim 12, wherein the through-electrode further includes a plurality of peripheral layers, each of which includes a ring-shaped semiconductor and an external electrode, externally of the external electrode.

17. A semiconductor device according to claim 12, wherein the through-electrode is directly connected to a bump or is connected to the bump via a wire, and wherein a plurality of semiconductor substrates are laminated together with an electric conduction therebetween via the bump.
